(19) United States
(12) Patent Application Publication
(10) Pub. No.: US 2008/0211090 A1
(43) Pub. Date: Sep. 4, 2008

(54) Packed Semiconductor Sensor Chip For Use In Liquids

(75) Inventors: Johannes Wilhelmus Weekamp, Eindhoven (NL); Menno Willem Jose Prins, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., Eindhoven (NL)

(21) Appl. No.: 11/994,438

(22) PCT Filed: Jun. 28, 2006
(86) PCT No.: PCT/IB2006/052160

§ 371 Date: Jan. 2, 2008

(30) Foreign Application Priority Data
Jul. 5, 2005 (EP) 05106080.4

(51) Int. Cl. H01L 23/498; H01L 21/60

(52) U.S. Cl. 257/734; 438/125; 438/113; 422/68.1; 257/E23.002; 257/E21.511

(57) ABSTRACT

The present invention provides a packed semiconductor sensor chip (10) in which the sensing circuit (17) is positioned at substantially the same level or above the level of the packaging (13). Because of this, when the sensor is immersed in a fluid, in particular in a liquid, for the detection of an analyte in the fluid, substantially the total top surface of the semiconductor sensor chip will be in contact with the fluid and thus detection results can be optimised.

The present invention relates to a packed semiconductor sensor chip and to a method for the manufacturing of such a packed semiconductor sensor chip. More particularly, the invention provides a packed semiconductor sensor chip with improved detection accuracy. The packed semiconductor sensor chip may be used as a biosensor or a chemical sensor for use in molecular diagnostics.

Sensors are widely used for measuring physical attributes or physical events. They output a functional reading of a measurement as an electrical, optical or digital signal. That signal is data that can be transformed into information by other devices. A particular example of a sensor is a biosensor. Biosensors are devices that detect the presence of (i.e. qualitative measurement) or measure a certain amount (i.e. quantitative measurement) of target molecules such as e.g. proteins, viruses, bacteria, cell components, cell membranes, spores, DNA, RNA, etc. in a liquid, such as for example blood, serum, plasma, saliva, tissue extract, interstitial fluid, cell-culture extract, food or feed extract, drinking water, . . . . The target molecules also are called the “analyte”. In almost all cases, a biosensor uses a surface that comprises specific recognition elements for capturing the analyte. Therefore, the surface of the sensor device may be modified by attaching specific molecules to it, which are suitable to bind the target molecules which are present in the liquid.

Biosensors are becoming more and more important. Low cost packaging is very important for disposable biosensors with electrical interconnections. One of the measuring principles is the counting of labelled molecules attached at predetermined sites on the biosensor. For example, the molecules may be labelled with magnetic particles or beads and these magnetic particles or beads can be detected with a magneto-resistive sensor. Such sensors can be made with conventional silicon wafer technology.

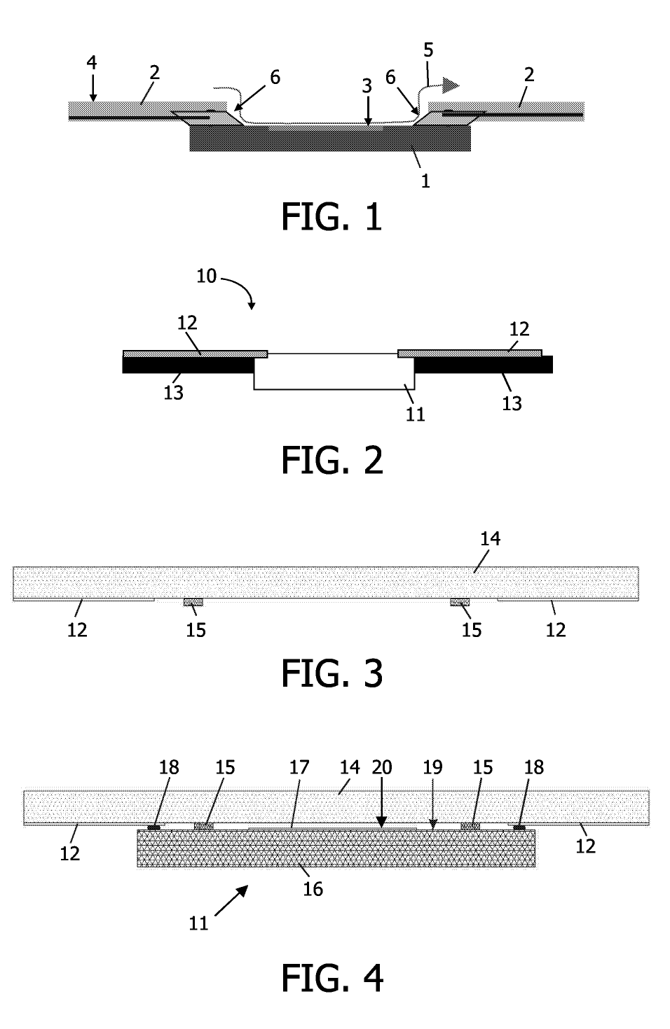

Most prior art packed semiconductor sensor chips suffer from the drawback that ‘walls’ exist between the package and the sensor chip surface, which decrease the efficiency of the sensor chip. An example is illustrated in FIG. 1. The sensor chip 1 is attached to the package 2 by wire bonding, which is a standard technology for interconnection. This technology, however, adds thickness on the sensor surface, which leads to a disadvantage of this package in that the top surface 3 of the sensor chip 1 is located at a distance from the top surface 4 of the package 2 so that analyte has to “dive” toward the sensor chip 2, i.e. the analyte, which is a fluid, needs to be guided along a corner (indicated by arrow 5 in FIG. 1) and will encounter irregular structures. This can imply the need for a large fluid sample, regions of low or stagnant flow, and possibly loss of material by adhesion to the walls 6. Alternative technologies with metalised vias or slots through the sensor substrate are expensive.

It is an object of the present invention to provide an improved packed semiconductor sensor chip and a method for the manufacturing of such a packed semiconductor sensor chip. An advantage of the present invention can be that it provides a packed semiconductor sensor chip with improved detection accuracy. A further advantage of the present invention is the provision of a packed semiconductor that is cheap to manufacture and/or uses substantially the whole of applied analyte. The packed semiconductor sensor chip may be used as a biosensor or a chemical sensor for use in molecular diagnostics. The above objective is accomplished by a device and a method according to the present invention.

Particular and preferred aspects of the invention are set out in the accompanying independent and dependent claims. Features from the dependent claims may be combined with features of the independent claims and with features of other dependent claims as appropriate and not merely as explicitly set out in the claims.

The present invention relates to the field of semiconductors, e.g. silicon-based sensor devices, where all the contacts of the circuit and the sensing elements are located on the top surface.

In a first aspect of the invention a packed semiconductor sensor chip is provided. The packed semiconductor sensor chip comprises:

a semiconductor sensor chip being provided with a sensing circuit and having a top surface, and

a package having a top surface,

wherein the top surface of the semiconductor sensor chip is above or substantially at a same level as the top surface of the package.

An advantage of the packed semiconductor is that, for measurements to be carried out, the sensor may be used with small amounts of fluid as there are substantially no walls between the top surface of the package and the top surface of the sensor chip onto which part of the fluid may stick, which part would thus be lost for measurement. Furthermore, the packed semiconductor sensor chip according to the present invention has an improved detection accuracy with respect to prior art sensor chips.

According to embodiments of the invention, the distance between the top surface of the package and the top surface of the semiconductor sensor chip may be between 0 and 50 μm. According to particular embodiments of the invention, the distance between the top surface of the package and the top surface of the semiconductor sensor chip may be lower than 30 μm, preferably lower than 20 μm, more preferably lower than 10 μm and most preferably lower than 5 μm, i.e. between 0 and 5 μm.

In embodiments according to the invention, the packed semiconductor sensor chip may furthermore comprise lead fingers or interconnects for making electrical connections to the semiconductor sensor chip. The lead fingers may have a thickness of between 5 and 15 μm and may have a width of between 50 and 100 μm. According to embodiments of the invention, the lead fingers, also called conductive leads or interconnects, may be as thin as possible such that the difference in height between the lead fingers and the top surface of the sensor chip is as small as possible.

According to embodiments of the invention, the packed semiconductor sensor chip may have recessed edges. When the packed semiconductor sensor chip according to this embodiments is immersed in a fluid, e.g. liquid or gas, for being used, substantially the total top surface of the semiconductor sensor chip will be in contact with the fluid and no loss of material to be detected to the walls of the semiconductor sensor can occur, because with respect to the prior art packed sensor chips, there are substantially no walls from the lead fingers down to the top surface of the semiconductor sensor chip.

According to an embodiment of the invention, the lead fingers may be provided with an electrically insulating coating, e.g. an organic or inorganic layer, in order to be electrically insulated from fluid comprising at least one analyte to be detected, because the fluid may generally be electrically conducting.

According to embodiments of the invention, the fluid comprising at least one analyte to be detected may be applied to the packed semiconductor sensor chip by immersing the packed sensor chip in the fluid. In other embodiments, the fluid may be applied by spraying the fluid over the packed semiconductor sensor chip. Moreover, in further embodiments of the invention, the fluid may also be applied to the packed semiconductor sensor chip in any other suitable way, e.g. by means of a micropipette in case of a liquid.

In an alternative embodiment, the fluid comprising at least one analyte to be detected may be comprised in a fluid-containing element that is separated from the sensor package. In that case, the fluid comprising the analyte to be detected is comprised in a disposable ‘biological’ part that is separated from and may be applied to a re-usable sensor head. The fluid-containing element may, for example, be a well or a lateral-flow device having a very thin bottom or wall. The sensor package may be pressed to a bottom or a wall of the fluid-containing element for allowing detection of the analyte present in the fluid.

Furthermore, the packed semiconductor sensor chip may, according to embodiments of the invention, furthermore comprise a coating of a biocompatible material, i.e. it may be made of a material that is suited for bio-measurements. The biocompatible material may for example be made of a material that is suitable for binding biological materials, e.g. polystyrene, nylon, or nitrocellulose. According to other embodiments of the present invention, the coating may be formed of materials which show a low biological or specific binding, such as e.g. polyethyleneglycol, or any other material known in the art with a low non-specific binding. In the latter case, the coating first needs to be biologically activated in order to couple biological receptor molecules to the coating in the vicinity of the sensor chip.

A coating may be applied to the package in different ways. For example, the material may be applied from a solution, for example by contact printing, non-contact printing, spraying or spin coating. The material of the coating may also be applied by lamination of a foil onto the package, for example, by adhering a thin foil onto the package, e.g. by using glue or by means of a heat treatment. Also a hybrid material may be applied to the package, e.g. a plastic foil that carries a material such as nitrocellulose suitable for binding biological materials. According to embodiments of the invention, the coating may have a thickness of between 0.1 and 30 μm.

The packed semiconductor sensor chip according to the first aspect of the invention may, for example, be a biosensor or a chemical sensor.

In a second aspect of the present invention, a method is provided for the manufacturing of a packed semiconductor sensor chip. The method comprises:

providing a semiconductor sensor chip provided with a sensing circuit and having a first top surface,

providing a temporary substrate with a second top surface, the second top surface comprising at least one lead finger, attaching the sensor chip to the temporary substrate, the first top surface facing the second top surface,

providing a package to the sensor chip, and

removing said temporary substrate,

wherein attaching the semiconductor sensor chip to the temporary substrate is performed such that the top surface of the semiconductor sensor chip is above or substantially at a same level as the top surface of the package.

An advantage of the method according to the second aspect of the present invention is that it leads to a packed semiconductor sensor device that may be used with small amounts of fluid as there are substantially no walls between the top surface of the package and the top surface of the sensor chip onto which part of the fluid may stack, which part would thus be lost for measurement. Furthermore, the method leads to a packed semiconductor sensor chip which has an improved detection accuracy with respect to prior art sensor chips.

The step of attaching the semiconductor sensor chip to the temporary substrate may, according to embodiments of the invention, be performed by means of one of a soldering process, ultrasonic bonding or gluing. According to an embodiment of the invention, attaching the semiconductor sensor chip to the temporary substrate may be performed by means of a soldering process. The soldering process may comprise:

providing solder balls at an upper surface of the substrate of the semiconductor sensor chip,

attaching the sensor chip to the temporary substrate, and

melting said solder balls.

According to embodiments of the invention, the step of removing the temporary substrate may be performed by wet etching using suitable etching solvents.

According to embodiments of the invention, the method may furthermore comprise providing a coating of biocompatible material on top of the packed semiconductor sensor chip. The thickness of the coating may be between 0.1 μm and 30 μm. The biocompatible material may for example be a material that is suitable for binding biological materials, e.g. polystyrene, nylon, or nitrocellulose. According to other embodiments of the present invention, the coating may be formed of materials which show a low biological or specific binding, such as e.g. polyethyleneglycol, or any other material known in the art with a low non-specific binding. In the latter case, the coating first needs to be biologically activated in order to couple biological receptor molecules to the coating in the vicinity of the sensor chip.

The coating of biocompatible material may be applied to the package in different ways. For example, the material may be applied from a solution, for example by contact printing, non-contact printing, spraying or spin coating. The material of the coating may also be applied by lamination of a foil onto the package, for example, by adhering a thin foil onto the package, e.g. by using glue or by means of a heat treatment. Also a hybrid material may be applied to the package, e.g. a plastic foil that carries a material such as nitrocellulose suitable for binding biological materials.

According to embodiments of the invention, the method may furthermore comprise:

providing a substrate having a substrate top surface, and comprising at least two sensing circuits on said substrate top surface for forming different sensor chips,

providing grooves between the at least two sensing circuits,

providing solder balls onto the substrate top surface, and

separating the substrate into a plurality of sensor chips before attaching the sensor chips to said temporary substrate.

In a third aspect of the invention, a packed sensor according to the first aspect of the invention may be used in molecular diagnostics.

The above and other characteristics, features and advantages of the present invention will become apparent from the following detailed description, taken in conjunction with the accompanying drawings, which illustrate, by way of example, the principles of the invention. This description is given for the sake of example only, without limiting the scope of the invention. The reference figures quoted below refer to the attached drawings.

FIG. 1 illustrates a packed biosensor according to the prior art.

FIG. 2 illustrates a packed semiconductor sensor chip according to a first embodiment of the present invention.

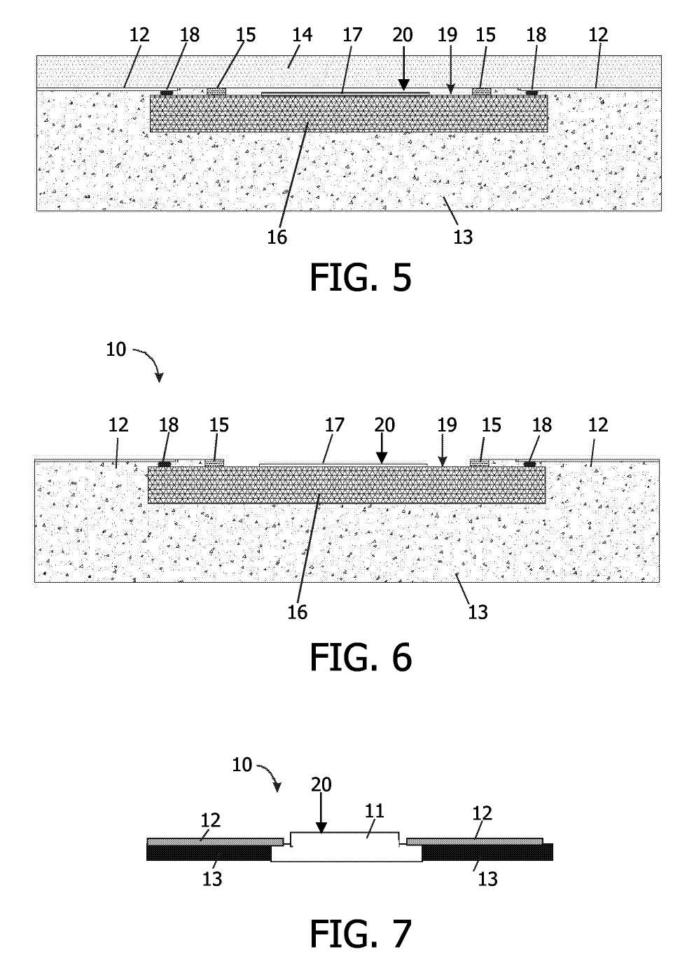

FIGS. 3 to 6 illustrate subsequent steps in the manufacturing of a packed semiconductor sensor chip according to FIG. 2.

FIG. 7 illustrates a packed semiconductor sensor chip according to a second embodiment of the invention.

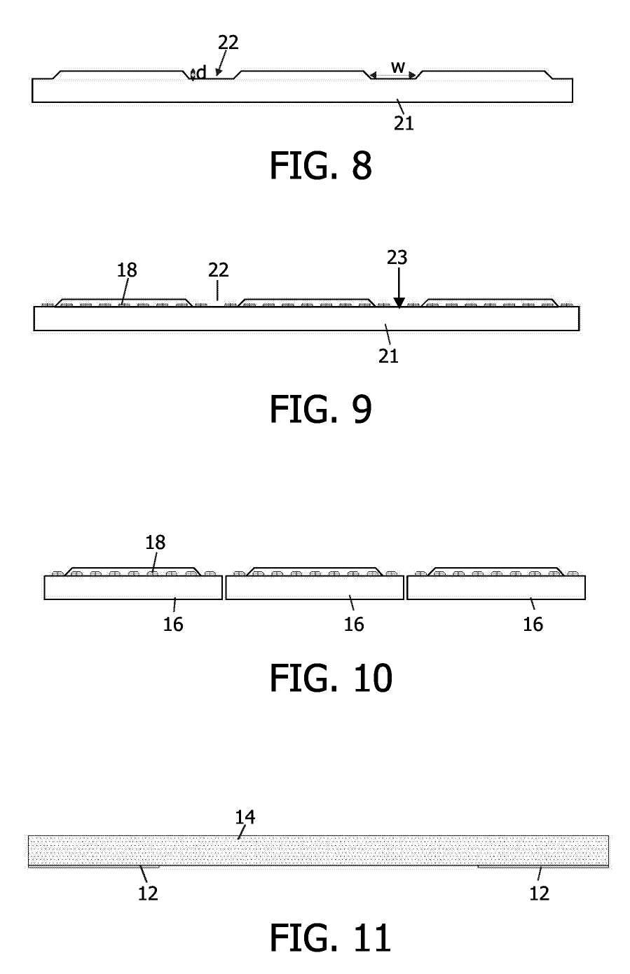

FIG. 8 to 10 illustrate subsequent steps in the manufacturing of semiconductor sensor chips with recessed edges.

FIG. 11 to 14 illustrate subsequent steps in the manufacturing of a packed semiconductor sensor chip according to FIG. 7.

FIG. 15 illustrates a packed semiconductor sensor chip according to a third embodiment of the invention.

In the different figures, the same reference signs refer to the same or analogous elements.

The present invention will be described with respect to particular embodiments and with reference to certain drawings but the invention is not limited thereto but only by the claims. Any reference signs in the claims shall not be construed as limiting the scope. The drawings described are only schematic and are non-limiting. In the drawings, the size of some of the elements may be exaggerated and not drawn on scale for illustrative purposes. Where an indefinite or definite article is used when referring to a singular noun e.g. “a” or “an”, “the”, this includes a plural of that noun unless something else is specifically stated.

Furthermore, the terms first, second, third and the like in the description and in the claims, are used for distinguishing between similar elements and not necessarily for describing a sequential or chronological order. It is to be understood that the terms so used are interchangeable under appropriate circumstances and that the embodiments of the invention described herein are capable of operation in other sequences than described or illustrated herein.

Moreover, the terms top, bottom, over, under and the like in the description and the claims are used for descriptive purposes and not necessarily for describing relative positions. It is to be understood that the terms so used are interchangeable under appropriate circumstances and that the embodiments of the invention described herein are capable of operation in other orientations than described or illustrated herein.

It is to be noticed that the term “comprising”, used in the claims, should not be interpreted as being restricted to the means listed thereafter; it does not exclude other elements or steps. It is thus to be interpreted as specifying the presence of the stated features, integers, steps or components as referred to, but does not preclude the presence or addition of one or more other features, integers, steps or components, or groups thereof. Thus, the scope of the expression “a device comprising means A and B” should not be limited to devices consisting only of components A and B. It means that with respect to the present invention, the only relevant components of the device are A and B.

The present invention provides a packed semiconductor sensor chip wherein the semiconductor sensor chip has a top surface which is above or substantially at a same level as the top surface of a package. This has the advantage that small amounts of fluid may be used for measurements to be carried out, as there are substantially no walls between the top surface of the package and the top surface of the sensor chip onto which part of the fluid may stack, which part would thus be lost for measurement. Furthermore, the packed semiconductor sensor chip according to the present invention has an improved detection accuracy with respect to prior art sensor chips.

The packed semiconductor sensor chip may be used for the detection of at least one analyte, such as e.g. proteins, viruses, bacteria, cell components, cell membranes, spores, DNA, RNA, . . . present in a fluid, such as e.g. blood, serum, plasma, saliva, tissue extract, interstitial fluid, cell-culture extract, food or feed extract, drinking water, . . . . The fluid may be a liquid or a gas, but may also be vacuum comprising at least one luminescent particle to be detected.

The packed semiconductor sensor chip may be immersed in the fluid that contains the analyte to be detected. However, for particular applications, the packed semiconductor sensor chip does not need to be immersed in the fluid but the fluid may, for example, be sprayed over the packed semiconductor sensor chip. Moreover, the fluid may also be applied to the packed semiconductor sensor chip in any other suitable way, e.g. by means of a micropipette in case of a liquid.

Alternatively, the fluid that comprises the at least one analyte to be detected may be comprised in a fluid-containing element that is separated from the packed semiconductor sensor chip. In that case, the fluid comprising the analyte to be detected is comprised in a disposable ‘biological’ part that is separated from and may be applied to a re-usable sensor head. The fluid-containing element may, for example, be a well or a lateral-flow device having a very thin bottom or wall. The sensor package may be pressed to a bottom or a wall of the fluid-containing element for allowing detection of the analyte present in the fluid.

In FIG. 2 a packed semiconductor sensor chip 10 according to a first embodiment of the invention is schematically illustrated. The packed semiconductor sensor chip 10 comprises a package 13, the top surface of which is below the top surface of the semiconductor sensor chip 11. The distance between the top surface of the package 13 and the top surface of the sensor chip 11 may be between 0 and 50 μm. In embodiments of the present invention, the top surface of the semiconductor sensor chip 11 may be substantially at the same level as the top surface of the package 13.

The semiconductor sensor chip 11 may preferably comprise silicon, but may also comprise GaAs or any other suitable semiconductor material. The semiconductor sensor chip 11 may, for example, be 1.4 mm×1.5 mm. It has to be understood that this is only an example, and that semiconductor sensor chips 11 with different sizes may be applied according to the present invention.

According to embodiments of the present invention, the semiconductor sensor chip 11 may be connected onto a lead frame, provided e.g. in the form of a lead frame-like interconnect foil. With “lead frame” is meant lead out fingers 12, which are conductive fingers, e.g. metal fingers, intended for connection to a semiconductor sensor chip 11 by finger bonding, the conductive, e.g. metal, fingers for example having been produced by punching or photo-fabrication from a conductive, e.g. metal, ribbon.

In the packed semiconductor sensor chip 10 according to embodiments of the invention, the interconnect or conductive lead 12 is located at substantially the same level or even below the level of the top surface of the sensor chip 11. This is contrary to prior art packed semiconductor sensor chips, where conductive interconnections to the outside world are made by means of wire bonding requiring a pre-determined height above the sensor chip surface, so that the top surface of a package including such wire bondings is located at a position above the top surface of the sensor chip.

FIG. 3 to FIG. 6 illustrate subsequent process steps for the manufacturing of the packed semiconductor sensor chip 10 that is illustrated in FIG. 2. For the sake of simplicity only the cross-section of one device is drawn in these Figures. However, in practice the invention may also be applied to an array of semiconductor sensor chips 11.

In a first step, illustrated in FIG. 3, a temporary substrate 14, which may be a metal substrate such as e.g. a copper substrate, or any other suitable substrate, is provided. The temporary substrate 14 may have a thickness which may be related to the ease of handling in standard equipment and may preferably be between 50 and 100 μm.

The temporary substrate 14 comprises a spacer 15, for example a seal ring, and conductive leads or lead fingers 12. The spacer 15, e.g. seal ring, may, for example, comprise a photo-definable polymer such as e.g. benzocyclobutene (BCB) or SU-8. The height of the spacer 15 may be between 5 and 15 μm. It is a function of the spacer 15 to seal the sensing circuit from packaging material during a further packaging step (see below).

The conductive leads 12 may have a thickness of between 5 and 15 μm, for example 10 μm, and a width between 50 and 100 μm, for example 75 μm. According to embodiments of the present invention, the conductive leads 12, also called interconnects, may be as thin as possible such that the difference in height between the conductive leads 12 and the top surface of the sensor chip 11 is as small as possible (see further).

According to embodiments, when the lead fingers 12 are in direct contact with the fluid comprising the analyte to be determined, the lead fingers 12 may be provided with an electrically insulating coating which may, for example, be an organic layer (e.g. a spincoated layer of a photoresist such as polysterene, epoxy, or any other suitable material that can be spincoated onto a substrate) or an inorganic layer (e.g. an oxide such as SiO₂ or a nitride such as Si₃N₄), in order to electrically insulate them from the sample fluid, because this fluid may generally be electrically conducting.

Next, according to the embodiment described, a semiconductor sensor chip 11 is attached to the temporary substrate 14 by using a flip chip technique. The semiconductor sensor chip 11 comprises a substrate 16 and a sensing circuit 17. The semiconductor sensor chip 11 may be attached to the temporary substrate 14 by, for example, soldering, ultrasonic bonding or gluing. Ultrasonic bonding is a bonding technique that uses ultrasonic energy and pressure to form the bond, without heating. In the example illustrated in FIG. 4, the semiconductor sensor chip 11 is attached to the temporary substrate 14 by soldering. Therefore, solder balls 18 are provided on the upper surface 19 of the semiconductor sensor chip substrate 16, i.e. that side of the semiconductor sensor chip substrate 16 that comprises the sensing circuit 17. The semiconductor sensor chip 11 is then positioned onto the temporary substrate 14 with its top surface 20 toward the temporary substrate 14. The semiconductor sensor chip 11 is positioned such that the solder balls 18 make contact with the conductive leads 12 on the temporary substrate 14 and then the solder balls 18 are melted to make a physical and electrical connection between the conductive leads 12 and the solder balls 18. This step is illustrated in FIG. 4.

After attaching the semiconductor sensor chip 11 to the temporary substrate 14 a sensor chip package 13 is provided. According to embodiments of the invention, this may be done by moulding, e.g. by overmoulding. The overmoulding process typically includes two major categories, i.e. insert moulding and multi-shot moulding. In the insert moulding process, one or more sub-components, which may be plastic or metal, are placed or “inserted” in the mould. This may be done by hand or automatically. A molten polymer, such as e.g. a thermoplastic elastomer (TPE), a thermoplastic urethane (TPU), a reinforced engineering thermoplastic (RETP) or any other suitable polymer, is then injected into the same cavity forming the package. Multi-shot moulding requires the use of multiple injection units, each independently injecting a desired plastic material into a more complex mould design forming a multi-component assembly. The moulding material may, for example, be a thermoset epoxy compound. The mould temperature may typically be 160° C. and the mould pressure may typically be 50 Bar.

In a next step, illustrated in FIG. 6, the temporary substrate 14 is removed. This may be done by techniques known by persons skilled in the art, such as e.g. wet selective etching using suitable etching solutions. For example, in the case of the temporary substrate 14 being formed of copper, the wet etching may be performed by the use of acid solvents, preferably ferric chloride solutions because in the reaction of ferric chloride with copper no significant fumes or gasses are produced. In that way, the packed semiconductor sensor chip 10 according to the first embodiment of the invention, with lead fingers 12 on top of the package 13, is obtained.

In the packed semiconductor sensor chip 11 according to the first embodiment, the total thickness of interconnect above the top surface 20 of the sensor chip 11, and thus also the distance between the top surface of the semiconductor sensor chip 11 and the top surface of the package 13, may be between 0 and 50 μm and may preferably be lower than 30 μm, preferably lower than 20 μm, more preferably lower than 10 μm and most preferably lower than 5 μm. With total thickness of interconnect, in the given example, is meant the thickness of the leads 12 together with the thickness of the solder balls 18. This means that the sensing circuit 17 and the conductive leads 12 are substantially lying in a same plane. Hence, the distance between the top surface 20 of the sensor chip 11 and the top surface of the package 13 may be controlled by the thickness of the conductive leads 12.

In the above, attaching of the temporary substrate 14 to the semiconductor sensor chip 11 has been described by means of providing and melting solder balls 18. However, in other embodiments according to the invention, instead of solder balls 18, a thin layer of solder material, gold bumps or gluing may also be used for attaching the temporary substrate 14 to the semiconductor sensor chip 11. In the cases where a thin layer of solder material, gold bumps or gluing with a conductive adhesive are used, with total thickness of interconnect is meant the thickness of the leads 12 together with the thickness of the material used for attaching the semiconductor sensor chip 11 to the temporary substrate 14.

Because of the above, in the packed semiconductor sensor chip 10 according to the first embodiment of the invention, the top surface 20 of the semiconductor sensor chip 11 is substantially at the same level as the top surface of the package 13. The interconnects or leads 12 are substantially at the same level as the top surface 20 of the semiconductor sensor chip 11. This implies that, in use, when the packed semiconductor sensor chip 11 is immersed in a fluid, for example a liquid or a gas, substantially the total top surface 20 of the semiconductor sensor chip 11 will be in contact with the fluid and no loss of material to be detected, e.g. by sticking to the walls of the semiconductor sensor, can occur, because with respect to the prior art packed semiconductor sensor chips, according to the present invention there are substantially no walls from the top of the package 13 down to the top surface 20 of the semiconductor sensor chip 11.

In a second embodiment of the invention a packed semiconductor sensor chip 10 is provided, where the top surface 20 of the semiconductor sensor chip 11 is at the same level or above the top surface of the package 13. The top surface 20 of the semiconductor sensor chip 11 may also be above the interconnect level (see FIG. 7).

For this reason, first a semiconductor sensor chip 11 with recessed edges is provided. FIGS. 8 to 10 illustrate subsequent steps in the manufacturing of such a semiconductor sensor chip 11 with recessed edges.

In a first step, a substrate 21 is provided comprising at least two sensing circuits (not shown in the Figure) for forming different semiconductor sensor chips 11. In a next step, grooves 22 are provided in the substrate 21 (see FIG. 8). The substrate 21 may preferably comprise Si, but may also comprise GaAs or any other suitable semiconductor material. The grooves 22 may have a depth d of between 30 and 50 μm and may have a width w determined by twice the required width for the interconnect of the semiconductor sensor chip 11 to the leads 12. The width w may be about 300 μm. According to embodiments of the invention, the grooves 22 may extend across the total length of the substrate 21. Grooves may be provided in two directions, e.g. substantially perpendicular to each other, for example if the sensing circuits are provided in an array on the substrate 21, so as to prepare divisions between the at least two sensing circuits provided on the substrate 21.

In this second embodiment the distance between the surface of the semiconductor sensor chip 11 and the leads 12 is determined by the depth of the grooves 22 minus the thickness of the interconnect leads 12.

In a next step, which is illustrated in FIG. 9, a top surface 23 of the substrate 21 is provided with interconnect bumps which may, in the example given in FIG. 9, be solder balls 18 for, in a later stadium, attaching the semiconductor sensor chips 11 to a temporary substrate 14 (see further). In other embodiments according to the invention, the interconnect bumps may also be gold bumps or conductive adhesive. The interconnect bumps are provided in the grooves, around the sensing circuits. After that, the different semiconductor sensor chips 11 are separated from each other (see FIG. 10). This may be done by conventional techniques known by persons skilled in the art. Each semiconductor sensor chip 11 comprises a substrate 16 and a sensing circuit (not shown in the Figure). In other embodiments according to the invention, the interconnect bumps may be applied after the semiconductor chips 11 are separated from each other or, in other words, after dicing. However, this is less preferred. The reason for that is mainly from a manufacturing point of view because it is easier to handle larger wafers. The smaller the wafers become on which devices have to be processed, the more complex assembling becomes.

Further processing of the packed semiconductor sensor chip 10 according to the second embodiment is similar to the process discussed for the packed semiconductor sensor chip 10 of the first embodiment of this invention. The subsequent process steps are illustrated in FIGS. 11 to 14.

A temporary substrate 14, which may be, for example, a metal substrate such as e.g. a copper substrate, or any other suitable substrate, is provided. The temporary substrate 14 may have a thickness of between 50 and 100 μm and comprises conductive leads 12 (see FIG. 11). The conductive leads 12 may have a thickness of between 5 and 15 μm, for example 10 μm. According to the invention, the conductive leads 12 or interconnects may be as thin as possible. The temporary substrate 14 may furthermore comprise a recessed region at the position of the protruding sensing circuit. For the clarity of the drawings, this is not illustrated in FIGS. 11 to 13. When the temporary substrate 14 has such a recessed region, the top surface 20 of the semiconductor sensor chip 11 will be above the top surface of the package 13. When no such recessed region is present in the temporary substrate 14 the top surface 20 of the semiconductor sensor chip 11 will be at the same level as the top surface of the package 13.

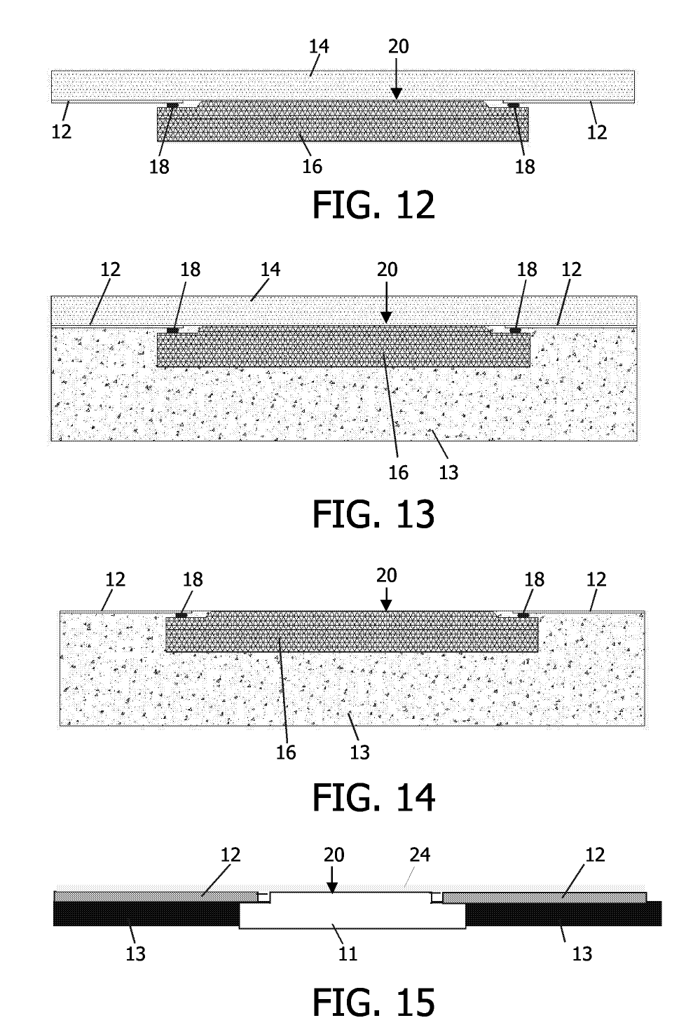

The semiconductor sensor chip 11 is then positioned onto the temporary substrate 14 with its upper surface 20 toward the temporary substrate 14. Next, the semiconductor sensor chip 11 is positioned onto the temporary substrate 14 by using the flip chip technique. In the example given, the semiconductor sensor chips 11 may be attached to the temporary substrate 14 by soldering the solder balls 18 provided during formation of the semiconductor sensor chips 11 with recessed edges. The semiconductor sensor chip 11 is positioned such that the solder balls 18 make contact with the conductive leads 12 and then the solder balls 18 are melted. This step is illustrated in FIG. 12.

After attaching the semiconductor sensor chip 11 to the temporary substrate 14 a sensor chip package 13 is provided (see FIG. 13). According to the invention, this may, for example, be done by overmoulding, as explained above. In other embodiments according to the invention, providing a sensor chip package 13 may be performed by filling or covering the semiconductor sensor chip 11 and the temporary substrate 14 with e.g. an epoxy. The package material may for example be plastic or metal, for example a molten polymer, such as e.g. a thermoplastic elastomer (TPE), a thermoplastic urethane (TPU), a reinforced engineering thermoplastic (RETP) or any other suitable polymer.

In a next step, illustrated in FIG. 14, the temporary substrate 14 is removed. This may be done by techniques known by persons skilled in the art, such as e.g. wet selective etching using proper etching solutions. For example, in the case of the temporary substrate 14 being formed of copper, the wet etching may be performed by the use of acid solvents, preferably ferric chloride solutions because in the reaction of ferric chloride with copper no significant fumes or gasses are produced. In that way, the packed semiconductor sensor chip 10 according to the second embodiment of the invention is obtained either with the top surface 20 of the semiconductor sensor chip 11 at the same level as the top surface of the package 13 (?) or with the top surface 20 of the semiconductor sensor chip 11 above the top surface of the package 13.

A semiconductor sensor chip 10 according to the second embodiment of the present invention implies that, when the packed semiconductor sensor chip 10 is immersed in a fluid, e.g. liquid or gas, for being used, substantially the total top surface 20 of the semiconductor sensor chip 11 will be in contact with the fluid and no loss of material to be detected to the walls of the semiconductor sensor can occur, because with respect to the prior art packed sensor chips, there are substantially no walls from the leads down to the top surface 20 of the semiconductor sensor chip 11.

In a third embodiment of the invention, the packed semiconductor sensor chip 10 according to the first or second embodiment of this invention may furthermore comprise a thin top coating 24 which is biocompatible, i.e. the thin top coating 24 may be made of a material that is suited for bio-measurements, and which may have a thickness of between 0.1 μm and 30 μm, preferably between 1 μm and 10 μm. The biocompatible material may for example be a material that is suitable for binding biological materials, e.g. polystyrene, nylon, or nitrocellulose. According to other embodiments of the present invention, the coating may be formed of materials which show a low biological or specific binding, such as e.g. polyethyleneglycol, or any other material known in the art with a low non-specific binding. In the latter case, the coating 24 first needs to be biologically activated in order to couple biological receptor molecules to the coating 24 in the vicinity of the semiconductor sensor chip 11.

A coating 24 may be applied to the package 13 in different ways. For example, the material may be applied from a solution, for example by contact printing, non-contact printing, spraying or spin coating. The material of the coating 24 may also be applied by lamination of a foil onto the package 13, e.g. by adhering a thin foil onto the package 13. This may, for example, be done by using glue or by means of a heat treatment. Also a hybrid material may be applied to the package 13, e.g. a plastic foil that carries a material such as nitrocellulose.

Due to the substantial flatness of the packed semiconductor sensor chips 11 according to the first and second embodiments, the biocompatible material may be applied with good integrity, continuity and homogeneity. Deposition of the biocompatible material may be performed by any suitable deposition method, for example printing, spincoating, spraying or evaporation.

An advantage of this embodiment is that the materials for the electronic parts, e.g. the sensing circuit 17, are uncoupled from the biomaterials, i.e. not in direct contact, so that these systems can be optimised independently.

The embodiments of the present invention provide a solution for providing a packed semiconductor sensor chip 10, wherein the contacts of the sensing circuit 17 and its sensing elements are all located on the top surface of the sensor chip 11, with interconnects to the ambient world. The interconnects may be used for connecting the packed sensor chip 10 e.g. to a reader device for extracting measurement results from the packed semiconductor chip 10. Compared to prior art methods for providing interconnects, e.g. wire bonding or mounting, the method according to the present invention does not add any height to the semiconductor sensor chip, thus leading to packaged sensor chips of which the top surface of the sensor chip is above or substantially at the same level as the top surface of the package, through which loss of material to be detected is minimised and hence detection results are optimised. Furthermore, because no additional height is introduced by the interconnects, the packed semiconductor sensor chip may be used in micro-fluidic systems where only a very small amount of liquid is provided to the sensor and thus losses of liquid should be minimised as much as possible.

The packed semiconductor sensor chips according to embodiments of the invention may be used as biosensors or chemical sensors and may be applied in molecular diagnostics.

It is to be understood that although preferred embodiments, specific constructions and configurations, as well as materials, have been discussed herein for devices according to the present invention, various changes or modifications in form and detail may be made without departing from the scope and spirit of this invention.

1. A packed semiconductor sensor chip (10) comprising:
a semiconductor sensor chip (11) being provided with a sensing circuit (17) and having a top surface (20), and
a package (13) having a top surface,
wherein the top surface (20) of the semiconductor sensor chip (11) is above or substantially at a same level as the top surface of the package (13).

2. A packed semiconductor sensor chip (10) according to claim 1, wherein the distance between the top surface of the package (13) and the top surface (20) of the semiconductor sensor chip (1) is between 0 and 50 μm.

3. A packed semiconductor sensor chip (10) according to claim 1, furthermore comprising lead fingers (12) for making electrical connections to the semiconductor sensor chip (11).

4. A packed semiconductor sensor chip (10) according to claim 3, wherein the lead fingers (12) have a thickness between 5 and 15 μm.

5. A packed semiconductor sensor chip (10) according to claim 1, wherein said sensor chip (11) has recessed edges.

6. A packed semiconductor sensor chip (10), according to claim 1, furthermore comprising a coating (24) of a biocompatible material.

7. A packed semiconductor sensor chip (10), according to claim 6, wherein the coating (24) has a thickness between 0.1 and 30 μm.

8. A packed semiconductor sensor chip (10) according to claim 1, wherein the sensor chip is a bio sensor.

9. A method for the manufacturing of a packed semiconductor sensor chip (10), the method comprising:
providing a semiconductor sensor chip (11) having a sensing circuit (17) and having a first top surface (20),
providing a temporary substrate (14) with a second top surface, the second top surface comprising at least one lead finger (12),
attaching the sensor chip (11) to the temporary substrate (14), the first top surface (20) facing the second top surface,
providing a package (13) to the sensor chip (11), and
removing said temporary substrate (14),
wherein attaching the semiconductor sensor chip (11) to the temporary substrate (14) is performed such that the top surface (20) of the semiconductor sensor chip (11) is above or substantially at a same level as the top surface of the package (13).

10. A method according to claim 9, wherein attaching the semiconductor sensor chip (11) to the temporary substrate (14) is performed by means of one of a soldering process, ultrasonic bonding or gluing.

11. A method according to claim 10, wherein attaching the semiconductor chip (11) to the temporary substrate (14) is performed by a soldering process.

12. A method according to claim 11, wherein the soldering process comprises:
providing solder balls (18) at an upper surface (19) of the substrate (16) of the semiconductor sensor chip (11),
attaching the sensor chip (11) to the temporary substrate (14), and
melting said solder balls (18).

13. A method according to claim 9, wherein removing said temporary substrate (14) is performed by a wet etching process.

14. A method according to claim 9, the method furthermore comprising providing a coating (23) of biocompatible material on top of the packed semiconductor sensor chip (11).

15. A method according to claim 9, the method furthermore comprising:
providing a substrate (21) having a substrate top surface, and comprising at least two sensing circuits (17) on said substrate top surface for forming different sensor chips (11),
providing grooves (21) between the at least two sensing circuits (17),
providing solder balls (18) onto the substrate top surface, and
separating the substrate 21 into a plurality of sensor chips (11) before attaching the sensor chips (11) to said temporary substrate (14).

16. A method according to claim 15, the method furthermore comprising providing a coating (23) of biocompatible material on top of the packed semiconductor sensor chip (11).

17. Use of a packed semiconductor sensor chip (10) according to claim 1 in molecular diagnostics.

18. Use of a packed semiconductor sensor chip (10) according to claim 4 in molecular diagnostics.
